(19) United States
(12) Patent Application Publication
(10) Pub. No.: US 2017/0362736 A1
(43) Pub. Date: Dec. 21, 2017

(54) APPARATUS AND METHOD FOR GROWING SILICON SINGLE CRYSTAL INGOT

(71) Applicant: LG SILTRON INCORPORATED, Gumi-si, Gyeongsangbuk-do (KR)

(72) Inventors: Sang Hee KIM, Gumi-si (KR); Young Ho JUNG, Gumi-si (KR)

(21) Appl. No.: 15/539,586

(22) PCT Filed: Aug. 14, 2015
(86) PCT No.: PCT/KR2015/008536

§ 371 Date: Jun. 23, 2017

(30) Foreign Application Priority Data
Apr. 6, 2015 (KR) 10-2015-0048187

(51) Int. Cl. C30B 29/06; C30B 30/04; C30B 15/30; H01L 21/02; C30B 15/14

(52) U.S. Cl. CPC C30B 29/06; H01L 21/02002; C30B 15/14; C30B 15/30; C30B 30/04

(57) ABSTRACT

An embodiment provides a method for growing a silicon single crystalline ingot that may include: preparing a silicon melt solution in a crucible; probing a seed in the silicon melt solution; rotating the seed and the crucible while applying a horizontal magnetic field to the crucible; and pulling up an ingot grown from the silicon melt solution, wherein an interface between the growing ingot and the silicon melt solution is formed downward from a horizontal plane at 1 to 5 millimeters, and a bulk micro defects (BMD) size of the grown ingot is between 55 and 65 nanometers.

### CROSS-REFERENCE TO RELATED PATENT APPLICATIONS

This application is a U.S. National Stage Application under 35 U.S.C. §371 of PCT Application No. PCT/KR2015/008536, filed Aug. 14, 2015, which claims priority to Korean Patent Application No. 10-2015-0048187, filed Apr. 6, 2015, whoseentire disclosures are hereby incorporated by reference.

### TECHNICAL FIELD

The embodiment relates to an apparatus and a method for growing a silicon single crystal ingot, and more particularly, to secure a uniformity of bulk micro defects (BMD) in a radial direction in a highly doped silicon single crystal ingot.

### BACKGROUND ART

In general, a silicon wafer is formed by a single crystal growing process for manufacturing a single crystal ingot, a slicing process for obtaining a thin disk-shaped wafer by slicing the single crystal ingot, a grinding process for machining an outer peripheral portion of a wafer to prevent cracking and distortion of the wafer obtained by the slicing process, a lapping process for removing damages due to mechanical processing remaining on the wafer, a polishing process for polishing the wafer, and a cleaning process for polishing the polished wafer and removing an abrasive or an foreign substance adhering to the wafer.

For a single crystal growth, a floating zone (FZ) method or a Czochralski (CZ) method (hereinafter referred to as CZ method) has been widely used. The CZ method is the most common method among those methods.

In the CZ method, a polycrystalline silicon is charged in a quartz crucible and heated and melted by a graphite heating element, and then a single crystal silicon ingot is grown by pulling up a seed while rotating the seed when the seed is immersed in a silicon melt solution formed as a result of melting and crystallization occurs at an interface.

In particular, oxygen is included in a silicon single crystal as crystal defects due to growth history and undesired impurities in a growing process of the silicon single crystal, and thus intruded oxygen in this manner is grown into oxygen precipitate due to heat applied during a manufacturing process of a semiconductor device. Although the oxygen precipitate shows beneficial characteristics such as reinforcing the strength of the silicon wafer and capturing metal pollution elements and serving as an internal gettering site, a leakage current and a fail of the semiconductor device are caused.

Therefore, even if the oxygen precipitate in a denuded zone from the wafer surface where the semiconductor device is to be formed to a predetermined depth is not substantially present, the wafer present in a predetermined density and distribution in a bulk region of a predetermined depth or more is required. Such oxygen precipitates and bulk stacking defects generated in the bulk region in the manufacturing process of the semiconductor device is generally referred to as bulk micor defects (BMD). Hereinafter, the oxygen precipitate in the bulk region and the BMD are used without distinction.

As a technique for providing such a wafer in which the concentration and distribution of BMD is controlled, there has been proposed techniques for controlling the BMD concentration by adjusting an initial oxygen concentration and a crystal defect concentration through a seed rotational speed, a crucible rotation speed, a melt gap which is a distance between the melt surface and a heat shield, a pull speed of the ingot, a design change of a hot zone, a third element doping such as nitrogen or carbon, which are process variables when growing a silicon single crystal ingot.

Furthermore, in addition to controlling those growing process variables and growth histories, controlling a BMD concentration and distribution through a heat treatment during a wafering process is required to be adjusted.

### DISCLOSURE

### Technical Problem

The embodiment is directed to providing a method for growing a silicon single crystal to secure a uniformity of bulk micro defects (BMD) in a radial direction.

### Technical Solution

The embodiment provides a method for growing a silicon single crystal ingot that may include: preparing a silicon melt solution in a crucible; probing a seed in the silicon melt solution; rotating the seed and the crucible while applying a horizontal magnetic field to the crucible; and pulling up an ingot grown from the silicon melt solution, wherein an interface between the growing ingot and the silicon melt solution is formed downward from a horizontal plane at 1 to 5 millimeters, and a bulk micro defects (BMD) size of the grown ingot is between 55 to 65 nanometers.

A temperature gradient in the ingot during growth of the ingot may be less than 34 Kelvin/cm.

A cooling time of a central region of the ingot may be longer than that of an edge region.

The silicon melt solution may have a resistivity of 20 mohm·cm (milliohm·cm) or less.

The silicon melt solution may be doped with a dopant of 3.24E18 atoms/cm³ or more.

The dopant may be boron.

A rotation speed of the seed at the time of growing the ingot may be 8 rpm or less.

A magnetic field of 3000 G (gauss) or more may be applied to the silicon melt solution at the time of growing the ingot,

A distance between the silicon melt solution and a heat shielding material may be 40 millimeters or more at the time of growing the ingot.

Another embodiment provides an apparatus for growing a silicon single crystal ingot, including: a chamber; a crucible provided inside the chamber and accommodating a silicon melt solution; a heater provided inside the chamber for heating the silicon melt solution; a heat shield material for shielding heat of the heater from the silicon melt solution toward the ingot; a pulling unit for rotating and pulling up the ingot to be grown from the silicon melt solution; and a magnetic field generating unit for applying a horizontal magnetic field to the crucible, wherein the pulling unit rotates a seed at a speed of 8 rpm or less.

The magnetic field generating unit may apply a magnetic field of 3000 G (gauss) or higher to the silicon melt solution.

The pulling unit may have a distance between the silicon melt solution and the heat shielding material 40 millimeters or more at the time of growing the ingot.

The heater may heat the crucible so that the temperature gradient in the ingot is less than 34 Kelvin/cm during growth of the ingot.

The silicon melt solution may have a resistivity of 20 mohm·cm (milliohm·cm) or less.

The pulling unit may pull up the ingot so that a cooling time of a central region of the ingot is longer than that of an edge region.

The apparatus for growing the silicon single crystal ingot may further include a dopant supply unit for doping the silicon melt solution at a concentration of 3.24E18 atoms/cm³ or more.

The pulling unit may pull up the ingot so that an interface between the growing ingot and the silicon melt solution is formed from 1 millimeter to 5 millimeters down from a horizontal plane.

### Advantageous Effects

According to the embodiment, a method of growing a silicon single crystal ingot can increase a thermal history of a center portion of an ingot, and thus the bulk micro defects (BMD) of a center portion and an edge portion of a manufactured wafer can be evenly distributed.

### DESCRIPTION OF DRAWINGS

FIG. 1 is a view illustrating an apparatus of manufacturing a single crystal ingot according to an embodiment.

FIG. 2A is a view illustrating a change of bulk micro defects (BMD) according to a longitudinal length growth (x-axis) at the time of body growth of a silicon single crystal ingot, and FIG. 2B is a view illustrating scattering of BMD in a wafer plane.

FIG. 3 is a view illustrating a difference in BMD between a center region and an edge region of a wafer.

FIGS. 4A and 4B are views illustrating a directionality of a growth interface at the time of growing the silicon single crystal ingot.

FIGS. 5A and 5B are views illustrating the directionality of the growth interface at the time of growing the silicon single crystal ingot according to a comparative example and an embodiment.

FIG. 6A shows a resistivity and a BMD distribution in the longitudinal direction of the ingot grown by the method according to the conventional comparative example and the embodiment.

FIG. 6B shows the BMD distribution in a radial direction of the wafer produced in the ingot grown by the method according to the embodiment.

### MODES OF THE INVENTION

Hereinafter, embodiments are provided in order to fully explain the invention, and will be described in detail with reference to accompanying drawings to help understanding of the invention. The embodiments may, however, be embodied in many different forms and are not to be construed as being limited to the embodiments set forth herein; rather, these embodiments are provided so that this disclosure is thorough and complete, and fully conveys the concept of embodiments to those skilled in the art.

In the description of embodiments, it should be understood that when an element is referred to as being “on or under” another element, the term “on or under” refers to either a direct connection between two elements or an indirect connection between two elements having one or more elements formed therebetween. In addition, when the term “on or under” is used, it may refer to a downward direction as well as an upward direction with respect to an element.

Further, the relational terms such as “first” and “second,” “over/upper portion/above,” and “below/lower portion/under” do not necessarily require or include any physical or logical relationship or sequence between devices or elements, and may also be used only to distinguish one device or element from another device or element.

Thicknesses of layers and areas in the drawings may be exaggerated, omitted, or schematically described for a convenient and precise description. In addition, the size of each component does not fully match the actual size thereof.

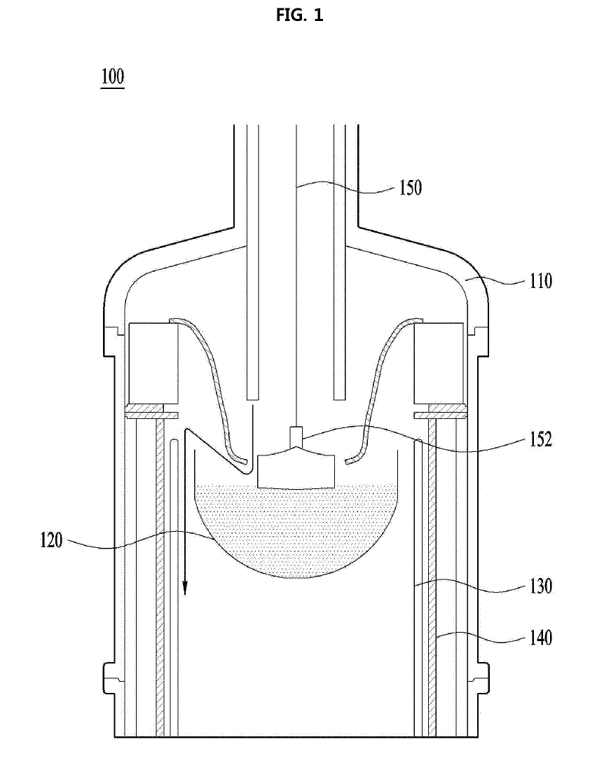

FIG. 1 is a view illustrating an apparatus of manufacturing a single crystal ingot according to an embodiment.

According to the embodiment, an apparatus of manufacturing a silicon single crystal ingot 100 may include a chamber 110, a crucible 120, a heater 130, a pulling unit 150, and the like. For example, the single crystal growing apparatus 100 according to the embodiment may include the chamber 110, the crucible 120 provided in the chamber 110 to receive a silicon melt solution, the heater 130 provided in the chamber 110 and configured to heat the crucible 120, and the pulling unit 150 coupled to a seed 152 at one end thereof.

The chamber 110 provides a space in which predetermined processes for growing the single crystal ingot for a silicon wafer used as an electronic component material such as a semiconductor are performed.

A radiant insulator 140 may be installed on an inner wall of the chamber 110 to prevent the heat of the heater 130 from being radiated to a side wall of the chamber 110.

In order to control an oxygen concentration at the time of growing the silicon single crystal, various factors such as a internal pressure condition at the time of rotation of the quartz crucible 120 may be controlled. For example, according to the embodiment, argon gas or the like may be injected into the chamber 110 of the silicon single crystal growing apparatus to control the oxygen concentration and then be discharged downward.

The crucible 120 is provided inside the chamber 110 to contain a silicon melt solution and may be made of quartz. A crucible support (not shown) made of graphite may be provided on the outside of the crucible 120 to support the crucible 120. The crucible support is fixedly installed on a rotating shaft (not shown), and the rotating shaft is rotated by a driving means (not shown) to rotate and elevate the crucible 120, so that a solid-liquid interface may maintain the same height.

The heater 130 may be provided inside the chamber 110 to heat the crucible 120, and may function to heat the silicon melt solution. For example, the heater 130 may have a cylindrical shape surrounding the crucible support. The heater 130 melts a high-purity polycrystalline silicon ingot placed in the crucible 120 which may be made into a silicon melt solution.

Although not shown, a heat shield material is provided on top of the crucible 120 to block heat generated from the heater 130 directed toward the silicon single crystal ingot, which is grown and pulled up.

In addition, a dopant supply unit (not shown) may dope the silicon melt solution with a dopant at a concentration of 3.24E18 atoms/cm³ or higher. Furthermore, a magnetic field generating unit is provided around the chamber 110, and thus a magnetic field may be applied to the crucible 120 in a horizontal direction.

In the embodiment, a Czochralski (CZ) method for growing a crystal by immersing a single crystal seed 152 in the silicon melt solution and slowly pulling up the seed 152 to grow a crystal may be employed as a manufacturing method for growing the silicon single crystal ingot.

The CZ method is described in detail as follows.

First, the silicon melt solution is prepared in the crucible 120, then a necking process is performed to probe the seed in the silicon melt solution to grow elongated crystals from the seed 152, then the crystal is grown in a diameter direction and subjected to a shouldering process to make a target diameter, thereafter, a body growing process is performed to grow crystals having a predetermined diameter, after the body growing has progressed by a certain length, the diameter of the crystal is gradually reduced, and finally a tailing process is performed to separate the crystal from the molten silicon, thereby completing the growth of the single crystal.

During the growth and pulling up of the ingot, a horizontal magnetic field may be applied while rotating the crucible. In addition, the heater 130 may heat the crucible 120 such that the temperature gradient in the ingot is less than 34 Kelvin/cm during ingot growth.

According to the embodiment, the silicon melt solution may be doped with B (boron) as a P-type dopant and doped with As (arsenic), P (phosphorus), Sb (antimony) or the like as an N-type dopant. At this point, when a high concentration of dopant is introduced, a growth rate/temperature gradient (V/G), that is, the rate of growth of the ingot relative to the temperature gradient may be changed depending on the dopant concentration. As a result, BMD may be changed particularly within a body region of the ingot.

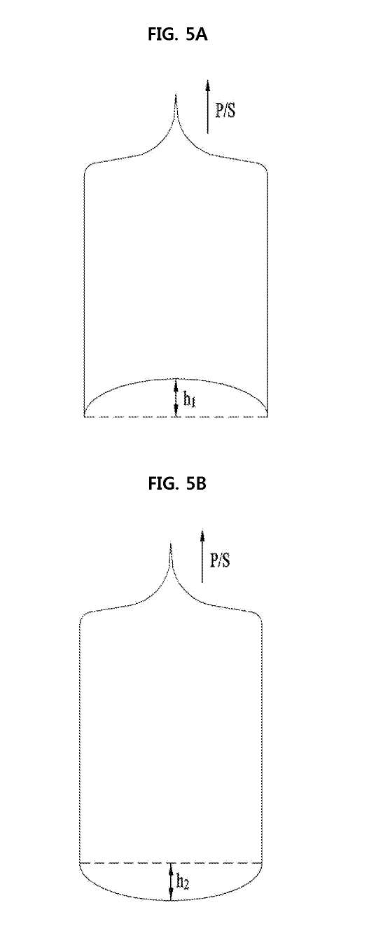

Further, the pulling unit 150 to which the seed 152 is coupled at one end thereof rotates the seed at a speed of 8 rpm or less, and the magnetic field generating unit may apply a magnetic field of 3000 G or more to the silicon melt solution. The pulling unit 150 may adjust a pulling speed of the ingot. Specifically, the pulling speed of the ingot is controlled so that a distance between the silicon melt solution and the heat shielding material as described above is 40 millimeters or more at the time of growing the ingot. Moreover, the ingot may be pulled up so that the interface between the growing ingot and the silicon melt solution is formed downward from a horizontal plane at 1 to 5 millimeters as shown in FIG. 5B and the like.

Further, the ingot may be pulled up so that a cooling time of a central region of the ingot is longer than that of an edge region.

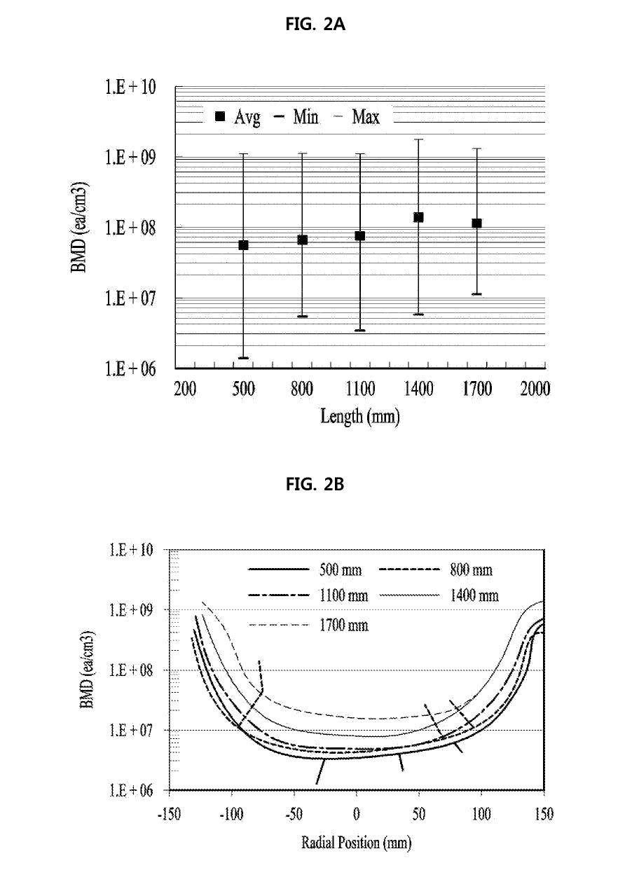

FIG. 2A is a view illustrating a change of bulk micro defects (BMD) according to a longitudinal length growth (x-axis) at the time of body growth of a silicon single crystal ingot, and FIG. 2B is a view illustrating scattering of BMD in a wafer plane.

As shown in FIG. 2A, BMD is continuously changed during ingot body growth. In particular, as shown in FIG. 2B, it can be seen that the BMD scattering is large even in the plane of the wafer, which is the same region in a longitudinal direction.

According to the embodiment, a change in a crystal region due to the growth rate/temperature gradient (V/G) change in a longitudinal direction of the ingot doped at a high concentration is controlled, so that a value G is less than 34 Kelvin/cm in an entire region of the ingot.

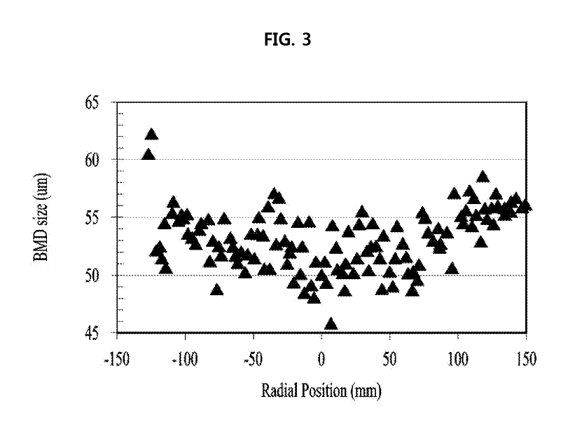

The silicon single crystal ingot grown by the process as described above has a resistivity of 20 mohm·cm or less, and boron as a dopant is doped to 3.24E18 atoms/cm³ or more. In addition, the BMD of the central region of the wafer is small as shown in FIG. 2B. Further, as shown in FIG. 3, the difference in BMD between the central region and the edge region of the wafer is large because the size of BMD in the central region of the wafer is smaller than the edge region of the wafer.

In order to solve the problem as descried above, a method of increasing the BMD size in the central region of the wafer may be used, but the silicon single crystal ingot is pulled and grown at the same speed in the central region and the edge region at the same time, and even when a thermal history is changed by changing the structure of a hot zone, the edge region other than the central region of the silicon single crystal ingot may be affected by the change of the thermal history. Accordingly, it is difficult to increase the size of BMD only in the central region of the wafer.

In the embodiment, in order to increase only the size of BMD of the central region of the silicon single crystal ingot, the cooling time of the central region is to be relatively long.

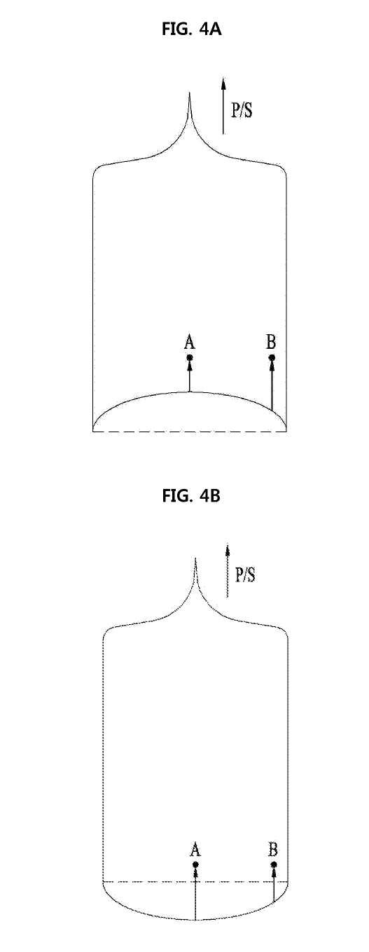

FIGS. 4A and 4B are views illustrating a directionality of a growth interface at the time of growing the silicon single crystal ingot,

As shown in FIGS. 4A and 4B, the pulling speed (P/S) of the silicon single crystal ingot is the same, but the cooling rate may not be the same.

That is, as shown in FIG. 4A, the interface of the bottom of the ingot is convex upward, so that the cooling time of a central region A of the wafer may be relatively shorter than that of an edge region B. In addition, as shown in FIG. 4B, the interface of the bottom of the ingot is convex downward, so that the cooling time of the central region A of the wafer may be relatively longer than that of the edge region B.

The wafer manufactured from the silicon single crystal ingot grown due to FIG. 4B is not simultaneously grown in the center region and the edge region, but the central region may be grown earlier to receive a longer thermal history to increase only the size of BMD of the central region.

FIGS. 5A and 5B are views illustrating the directionality of the growth interface at the time of growing the silicon single crystal ingot according to a comparative example and an embodiment.

According to the comparative example of FIG. 5A, the interface of a lower portion of the single crystal ingot is convex by a height (h₁) from the horizontal plane shown by the dotted line in an upward direction. In addition, according to the comparative example of FIG. 5B, the interface of the lower portion of the single crystal ingot is convex by a height (h₂) from the horizontal plane shown by the dotted line in the upward direction. As shown in FIGS. 5A and 5B, the seed is rotated at a speed of 8 rpm or less and the intensity of the magnetic field is 3,000 G (gauss) or more to lower the G value (temperature gradient), and thus the melt gap, which is the distance between the silicon melt solution and the heat shielding material, may be 40 mm or more.

Table 1 shows BMD changes in the center and edge regions of the wafer depending on the shape of the growth interface, and the height of the growth interface represents h₁ and h₂ in FIGS. 5A and 5B. Accordingly, in the case of +value, a curve is convex upward, but in the case of −value, a curve is convex downward.

TABLE 1

| | Height of | BMD of the | | Degree of |
|---|---|---|---|---|
| | the growth | central | BMD of the | BMD change |
| | interface | region | edge region | (Log |
| | (mm) | (Pieces/cm³) | (Pieces/cm³) | conversion) |
| Comparative | +5 | 5.44E6 | 6.98E8 | 2.11 |
| example 1 | | | | |
| Comparative | +2 | 2.26E7 | 4.50E8 | 1.30 |
| example 2 | | | | |
| Embodiment 1 | −2 | 1.29E8 | 2.81E8 | 0.34 |
| Embodiment 2 | −5 | 6.30E8 | 1.11E9 | 0.25 |

According to Comparative Examples 1 and 2, the growth interface of the silicon single crystal ingot is convex upward, and according to Embodiments 1 and 2, the growth interface of the silicon single crystal ingot may be convex downward.

As shown in Table 1, the growing interface of the silicon single crystal ingot doped at a high concentration is convexly controlled downward, so that the degree of BMD change is small and the uniformity of the BMD concentration in the radial direction may be ensured.

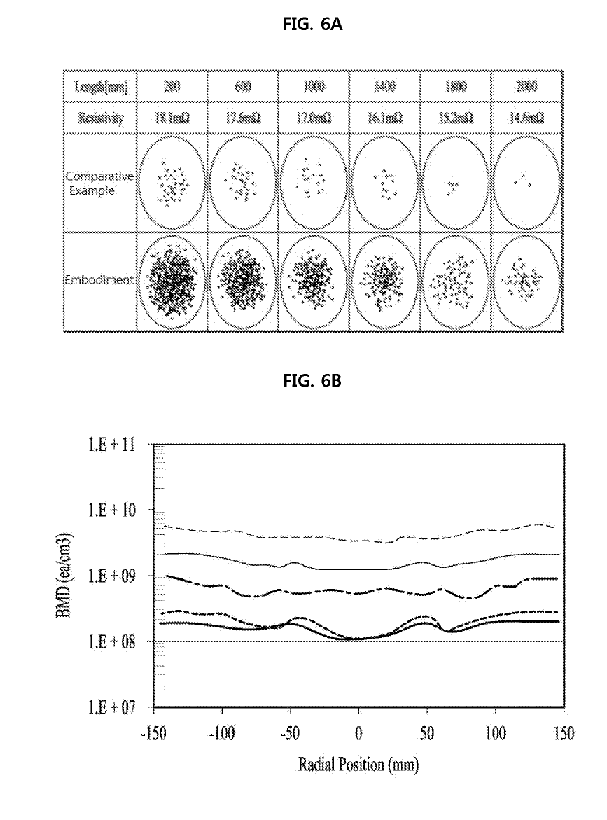

FIG. 6A shows a resistivity and a BMD distribution in the longitudinal direction of the ingot grown by the method according to the conventional comparative example and the embodiment, and a deviation of BMD in the longitudinal direction may be within 100 times. The wafer manufactured in the ingot grown by the method according to the embodiment as shown in FIG. 6B has a uniform distribution of BMD in an in-plane direction (transverse direction) and the deviation may be less than 0.4 as shown in Table 1. Here, the ‘in-plane’ may be a lateral direction as shown in FIG. 5B, and the like.

When the silicon single crystal ingot is grown by the process as described above, BMD of the center portion and the edge portion of the manufactured wafer are evenly distributed, thereby capable of improving the quality of the wafer.

Although embodiments have been mostly described above, they are only examples and do not limit the present invention and a person skilled in the art may appreciate that several variations and applications not presented above may be made without departing from the essential characteristic of embodiments. For example, each of components described in detail in the embodiment may be implemented in a modifiable manner. Also, it should be construed that differences related to such variations and applications are included in the scope of the present invention defined in the appended claims.

### INDUSTRIAL APPLICABILITY

1. A method of growing a silicon single crystal ingot, comprising:
preparing a silicon melt solution in a crucible;
probing a seed in the silicon melt solution;
rotating the seed and the crucible while applying a horizontal magnetic field to the crucible; and
pulling up an ingot to be grown from the silicon melt solution,
wherein an interface between the growing ingot and the silicon melt solution is formed downward from a horizontal plane at 1 millimeter to 5 millimeters, and a bulk micro defects (BMD) size of the grown ingot is between 55 nanometers and 65 nanometers.

2. The method of growing the silicon single crystal ingot of claim 1, wherein a temperature gradient in the ingot during growth of the ingot is less than 34 Kelvin/cm.

3. The method of growing the silicon single crystal ingot of claim 1, wherein a cooling time of a center region of the ingot is longer than that of an edge region.

4. The method of growing the silicon single crystal ingot of claim 1, wherein the silicon melt solution has a resistivity of 20 mohm·cm or less.

5. The method of growing the silicon single crystal ingot of claim 1, wherein the silicon melt solution is doped with a dopant of 3.24E18 atoms/cm³ or more.

6. The method of growing the silicon single crystal ingot of claim 5, wherein the dopant is boron.

7. The method of growing the silicon single crystal ingot of claim 1, wherein the seed is rotated at a rotation speed of 8 rpm or less at the time of growing the ingot.

8. The method of growing the silicon single crystal ingot of claim 1, wherein a magnetic field of 3000 G (gauss) or more at the time of growing the ingot is applied to the silicon melt solution.

9. The method of growing the silicon single crystal ingot of claim 1, wherein a distance between the silicon melt solution and a heat shielding material at the time of growing the ingot is 40 millimeters or more.

10. A silicon single crystal ingot growing apparatus comprising:
a chamber;
a crucible provided inside the chamber and accommodating a silicon melt solution;
a heater provided inside the chamber and heating the silicon melt solution;
a heat shield material for shielding heat of the heater from the silicon melt solution toward the ingot;
a pulling unit for rotating and pulling up the ingot to be grown from the silicon melt solution; and
a magnetic field generating unit for applying a horizontal magnetic field to the crucible,
wherein the pulling unit rotates a seed at a speed of 8 rpm or less.

11. The silicon single crystal ingot growing apparatus of claim 10, wherein the magnetic field generating unit applies a magnetic field of 3000 G (gauss) or higher to the silicon melt solution.

12. The silicon single crystal ingot growing apparatus of claim 10, wherein the pulling unit has a distance between the silicon melt solution and the heat shielding material 40 millimeters or more at the time of growing the ingot.

13. The silicon single crystal ingot growing apparatus of claim 10, wherein the heater heats the crucible so that a temperature gradient in the ingot is less than 34 Kelvin/cm during growth of the ingot.

14. The silicon single crystal ingot growing apparatus of claim 10, wherein the silicon melt solution has a resistivity of 20 mohm·cm or less.

15. The silicon single crystal ingot growing apparatus of claim 10, wherein the pulling unit pulls up the ingot so that a cooling time of a central region of the ingot is longer than that of an edge region.

16. The silicon single crystal ingot growing apparatus of claim 10, further comprising a dopant supply unit for doping the silicon melt solution at a concentration of 3.24E18 atoms/cm³ or more.

17. The silicon single crystal ingot growing apparatus of claim 10, wherein the pulling unit pulls up the ingot so that an interface between the growing ingot and the silicon melt solution is formed from 1 millimeter to 5 millimeters down from a horizontal plane.

18. A silicon single crystal ingot growing apparatus comprising:
a chamber;
a crucible provided inside the chamber and accommodating a silicon melt solution;
a heater provided inside the chamber and heating the silicon melt solution;
a heat shield material for shielding heat of the heater from the silicon melt solution toward the ingot;
a pulling unit for rotating and pulling up the ingot to be grown from the silicon melt solution; and
a magnetic field generating unit for applying a horizontal magnetic field to the crucible,
wherein the pulling unit pulls up the ingot so that an interface between the growing ingot and the silicon melt solution is formed from 1 millimeter to 5 millimeters down from a horizontal plane.

19. The silicon single crystal ingot growing apparatus of claim 18, wherein the pulling unit has a distance between the silicon melt solution and the heat shielding material 40 millimeters or more at the time of growing the ingot.

20. The silicon single crystal ingot growing apparatus of claim 18, wherein the pulling unit pulls up the ingot so that a cooling time of a central region of the ingot is longer than that of an edge region.
